(19) United States
(12) Patent Application Publication
(10) Pub. No.: US 2026/0074548 A1
(43) Pub. Date: Mar. 12, 2026

(54) METHOD AND APPARATUS FOR DETERMINING BATTERY CHARGING STATE

(71) Applicant: Samsung Electronics Co., Ltd, Suwon-si (KR)

(72) Inventors: Chanhyuk Lim, Suwon-si (KR); Dongjoon Lee, Suwon-si (KR); Hyunpyo Lee, Suwon-si (KR)

(21) Appl. No.: 19/271,060

(22) Filed: Jul. 16, 2025

(30) Foreign Application Priority Data
Sep. 12, 2024 (KR) 10-2024-0124999

(51) Int. Cl. H02J 7/00; G01R 31/364; G01R 31/3842; G01R 31/389; H01M 10/44

(52) U.S. Cl. CPC H02J 7/96; G01R 31/364; G01R 31/3842; G01R 31/389; H01M 10/44; H02J 7/82

(57) ABSTRACT

A method of determining a battery charging state includes measuring a voltage of a battery by a voltage measuring unit, calculating a compensation voltage for compensating for a voltage drop caused by a second resistance of a connection module disposed between the battery and the voltage measuring unit, and charging the battery, based on a total voltage defined as a sum of the compensation voltage and a cut-off voltage that is determined by a first resistance of the battery.

This application claims priority to Korean Patent Application No. 10-2024-0124999, filed on Sep. 12, 2024, and all the benefits accruing therefrom under 35 U.S.C. § 119, the content of which in its entirety is herein incorporated by reference.

### BACKGROUND

### 1. Field

The disclosure relates to a method, computer program, and apparatus for determining the charging state of a battery.

### 2. Description of the Related Art

Batteries are used as power sources for mobile devices and electric vehicles, and various battery charging methods have been proposed. A constant current-constant voltage (“CC-CV”) charging method is a common approach in which a battery is charged with a constant current until the voltage of the battery reaches a predetermined level, and then, the battery is charged with a constant voltage until the charging current reaches a preset low level having a relatively low value. In addition, there are other charging methods, such as a multistep charging method in which charging is performed in multiple steps using constant currents that vary from high to low, and a pulse charging method in which charging is performed by repeatedly applying pulse current over short periods of time.

### SUMMARY

A significant amount of time is desired in CV charging mode in the CC-CV charging method, and thus the CC-CV charging method is not suitable for rapid charging. The multistep charging method and the pulse charging method result in battery degradation due to rapid charging. As more people use electric vehicles equipped with multiple battery racks that are electrically connected to each other, the demand for rapid charging also increases. Charging methods based on experience, rather than considering the internal states of batteries, have limitations in controlling battery degradation and reducing charging time. There is a need to develop battery charging techniques that improve battery lifespan characteristics while supporting rapid charging.

Provided are a method, computer program, and apparatus for determining the charging state of a battery to reduce the duration of charging.

Provided are a method, computer program, and apparatus for determining the charging state of a battery while monitoring the state of the battery during charging.

Provided are a method, computer program, and apparatus for determining the charging state of a battery while protecting a battery charging device from risky overvoltage situations during charging.

Additional features will be set forth in part in the description which follows and, in part, will be apparent from the description, or may be learned by practice of the presented embodiments of the disclosure.

In an embodiment of the disclosure, a method of determining a battery charging state includes measuring a voltage of a battery by a voltage measuring unit, calculating a compensation voltage for compensating for a voltage drop caused by a second resistance of a connection module disposed between the battery and the voltage measuring unit, and charging the battery, based on a total voltage defined as a sum of the compensation voltage and a cut-off voltage that is determined by a first resistance of the battery.

In an embodiment, the battery may include a plurality of battery cells, and the connection module may include a collector module and a connection member. The collector module may electrically connect electrodes of the plurality of battery cells to each other, and the connection member may be disposed between the battery and the voltage measuring unit to electrically connect the battery and the voltage measuring unit to each other.

In an embodiment, the second resistance of the connection module may be determined by adding up resistances generated by the collector module and the connection member.

In an embodiment, the charging the battery may sequentially include charging the battery in a constant-current charging mode, and charging the battery in a constant-voltage charging mode.

In an embodiment, in the constant-current charging mode, a charging voltage may increase to the total voltage.

In an embodiment, in the constant-current charging mode, the compensation voltage may be determined by a product of the second resistance and a current applied in the constant-current charging mode.

In an embodiment, the method may further include measuring a charging current of the battery by a current measuring unit, where, in the constant-voltage charging mode, the charging the battery may be performed in multiple steps by sequentially reducing a charging voltage.

In an embodiment, in each of the multiple steps, the compensation voltage may be determined by a product of the charging current and the second resistance.

In an embodiment, in a first step of the multiple steps, constant-voltage charging the battery may be performed with a first total voltage determined by a sum of the cut-off voltage and a compensation voltage that is determined by a product of the second resistance and a first charging current preset to be less than the charging current in the constant-current charging mode, and when the charging current of the battery measured by the current measuring unit reduces to the first charging current, constant-voltage charging the battery may be performed in a second step of the multiple steps with a second total voltage determined by a sum of the cut-off voltage and a compensation voltage that is determined by a product of the second resistance and a second charging current less than the first charging current. The number of multiple steps may be set to be any value to perform this multistep constant-voltage charging the battery until the state of charge of the battery reaches a target state.

In an embodiment, the method may further include measuring a current of the battery in real time by a current measuring unit, where, in the constant-voltage charging mode, the charging the battery may be performed with a total voltage determined by a sum of the cut-off voltage and a compensation voltage that is determined by a product of the second resistance and the current of the battery measured in real time.

In an embodiment, the charging the battery may be performed at a first C-rate, where, in the constant-current charging mode, the charging the battery may be performed based on the total voltage, and in the constant-voltage charging mode, the charging the battery may be performed based on the cut-off voltage.

In an embodiment, the charging the battery may be performed at a second C-rate greater than a first C-rate, where the charging the battery may be performed based on the total voltage in the constant-current charging mode and the constant-voltage charging mode.

In an embodiment of the disclosure, a computer program is stored in a non-transitory recording medium for executing the method by a computing device.

In an embodiment of the disclosure, there is provided an apparatus for determining a battery charging state. The apparatus includes a memory storing a second resistance generated by a connection module disposed between a battery and a voltage measuring unit configured to measure a voltage of the battery, and a processor configured to calculate a compensation voltage for compensating for a voltage drop caused by the second resistance of the connection module and, based on a total voltage defined as a sum of the compensation voltage and a cut-off voltage that is determined by a first resistance of the battery, determine a charging state of the battery.

In an embodiment, the battery may include a plurality of battery cells, and the connection module may include a collector module and a connection member. The collector module may electrically connect the plurality of battery cells to each other, and the connection member may be disposed between the collector module and the voltage measuring unit to electrically connect the battery and the voltage measuring unit to each other. The processor may be further configured to determine the second resistance of the connection module by adding up resistances of the collector module and the connection member.

In an embodiment, the processor may be further configured to control the battery to be charged in a constant-current charging mode, and when a set condition is satisfied, control the battery to be charged in a constant-voltage charging mode.

In an embodiment, the processor may be further configured to increase a charging voltage to the total voltage in the constant-current charging mode.

In an embodiment, the processor may be further configured to determine the compensation voltage as a product of the second resistance and a constant current of the battery in the constant-current charging mode.

In an embodiment, the apparatus may further include a current measuring unit configured to measure a current of the battery, where the processor may be further configured to determine the compensation voltage as a product of the second resistance and the current of the battery measured in the constant-voltage charging mode.

In an embodiment, the apparatus may further include a current measuring unit configured to measure a current of the battery, where the processor may be further configured to control the battery to be charged in multiple steps in the constant-voltage charging mode by sequentially reducing a charging voltage.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a block diagram schematically illustrating an embodiment of a battery pack;

FIG. 2 is a perspective diagram schematically illustrating an embodiment of a battery;

FIG. 3 is a plan diagram illustrating an embodiment of an unfolded battery;

FIG. 4 is a graph illustrating current and voltage profiles during constant-current charging and constant-voltage charging, according to Comparative Example 1;

FIG. 5 is a diagram schematically illustrating an embodiment of a battery and a voltage measuring unit;

FIG. 6 is a graph illustrating current and voltage profiles during constant-current charging and constant-voltage charging, according to Comparative Example 2.

FIG. 7A is a flowchart illustrating an embodiment of a method of determining the charging state of a battery;

FIG. 7B is a flowchart illustrating an embodiment of a method of determining the charging state of a battery;

FIG. 8 is a graph illustrating current and voltage profiles during constant-current charging and constant-voltage charging, according to Embodiment 1;

FIG. 9 is a graph illustrating current and voltage profiles during constant-current charging and constant-voltage charging, according to Embodiment 2;

FIG. 10 is a graph illustrating current and voltage profiles during constant-current charging and constant-voltage charging, according to Embodiment 3;

FIG. 11 is a graph illustrating current and voltage profiles during constant-current charging and constant-voltage charging, according to Embodiment 4;

FIG. 12 is a graph illustrating current and voltage profiles during constant-current charging and constant-voltage charging, according to Comparative Example 3;

FIG. 13 is a graph illustrating current and voltage profiles during constant-current charging and constant-voltage charging, according to Comparative Example 4;

FIG. 14 is a graph illustrating current and voltage profiles during constant-current charging and constant-voltage charging, according to Embodiment 5;

FIG. 15 is a graph illustrating current and voltage profiles during constant-current charging and constant-voltage charging, according to Embodiment 6;

FIG. 16 is a graph comparing battery charging times at a first C-rate;

FIG. 17 is a graph comparing battery charging times at a second C-rate;

FIG. 18 is a diagram illustrating an embodiment of a vehicle; and

FIG. 19 is a diagram illustrating an embodiment of a terminal.

### DETAILED DESCRIPTION

Reference will now be made in detail to embodiments, embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features. As used herein, the term “and/or” includes any and all combinations of one or more of the associated listed items. Expressions such as “at least one of,” when preceding a list of elements, modify the entire list of elements and do not modify the individual elements of the list.

The inventive concept may have various different forms and various embodiments, and illustrative embodiments are described below with reference to the accompanying drawings. However, the inventive concept is not limited to the illustrative embodiments, and it should be understood that the idea and technical scope of the inventive concept cover all the modifications, equivalents, and replacements.

In the following description, terms are used only for explaining illustrative embodiments while not limiting the scope of the inventive concept. The terms of a singular form may include plural forms unless otherwise mentioned. The terms “comprises” and/or “comprising” used herein specify the presence of stated features, numbers, steps, processes, elements, components, materials, or combinations thereof but do not preclude the presence or addition of one or more other features, numbers, steps, processes, elements, components, materials, or combinations thereof.

Hereinafter, apparatuses of the disclosure will be described in embodiments with reference to the accompanying drawings. In the drawings, like reference numerals refer to like elements, and the sizes of elements may be exaggerated for clarity of illustration. The embodiments described herein are for illustrative purposes only, and various modifications may be made therein.

In the following description, when an element is referred to as being “above” or “on” another element, it may be directly on the other element while making contact with the other element or may be above the other element without making contact with the other element. The terms of a singular form may include plural forms unless otherwise mentioned. It will be further understood that the terms “includes” and/or “including” used herein specify the presence of stated features or elements, but do not preclude the presence or addition of one or more other features or elements.

An element referred to with the definite article or a demonstrative determiner may be construed as the element or the elements even though it has a singular form. Operations of a method may be performed in an appropriate order unless explicitly described in terms of order or described to the contrary. Operations of a method are not limited to the stated order thereof.

In the disclosure, terms such as “unit” or “module” may be used to denote a unit that has at least one function or operation and may be implemented with hardware (e.g., a circuitry), software, or a combination of hardware and software.

Furthermore, line connections or connection members between elements depicted in the drawings represent functional connections and/or physical or circuit connections as one of the embodiments, and in actual applications, they may be replaced or embodied with various additional functional connections, physical connections, or circuit connections.

Examples or exemplary terms are just used herein to describe technical ideas and should not be considered for purposes of limitation unless defined by the claims.

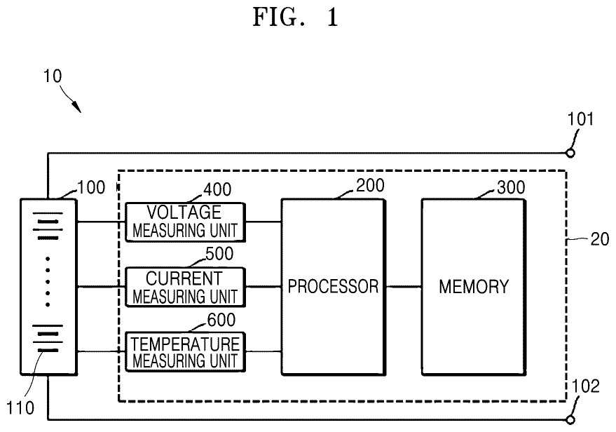

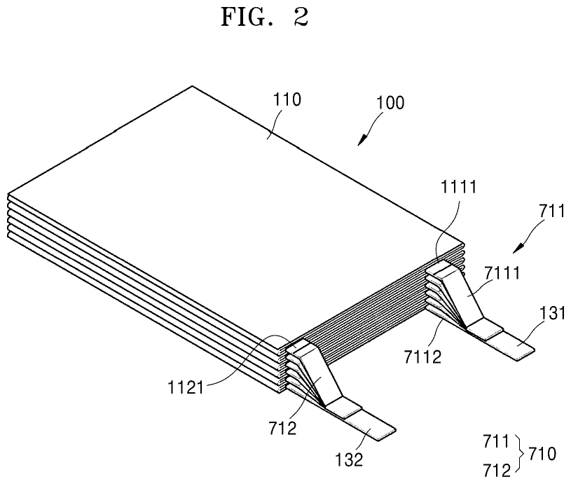

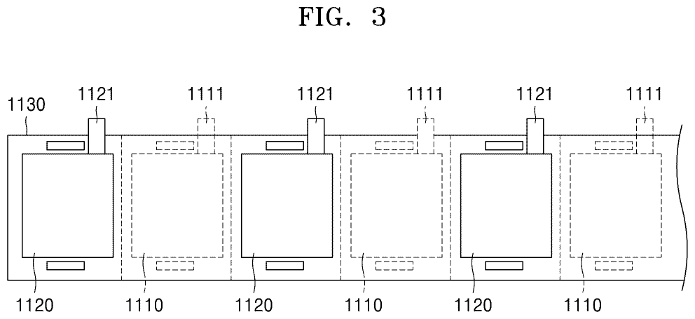

FIG. 1 is a block diagram schematically illustrating an embodiment of a battery pack 10. FIG. 2 is a perspective view schematically illustrating an embodiment of a battery 100. FIG. 3 is a plan view illustrating an embodiment of an unfolded state of the battery 100.

Referring to FIGS. 1 to 3, in an embodiment, the battery pack 10 may include the battery 100 and a battery charging state determination apparatus 20.

The battery 100 may include at least one battery cell 110, and the at least one battery cell 110 may be a rechargeable secondary battery cell. In an embodiment, the at least one battery cell 110 may include at least one selected from nickel-cadmium battery cells, lead storage battery cells, nickel-metal hydride battery (NiMH) cells, lithium-ion battery cells, lithium polymer battery cells, sodium-ion battery cells, and sulfide all-solid-state battery cells, for example.

In an embodiment, the at least one battery cell 110 may include first electrodes 1110, second electrodes 1120, a separator 1130, and lead tabs. The lead tabs may include first collector tabs 1111 respectively connected to the first electrodes 1110, and second collector tabs 1121 respectively connected to the second electrodes 1120.

In an embodiment, the battery 100 may be implemented in a stacked form in which the separator 1130 is folded in a zigzag shape, and the first electrodes 1110 and the second electrodes 1120 are respectively inserted into spaces between folded sections of the separator 1130. However, the disclosure is not limited thereto. In an embodiment, the first electrodes 1110 (hereinafter referred to as “negative electrodes 1110”) and the second electrodes 1120 (hereinafter referred to as “positive electrodes 1120”) may be placed on opposite sides of the separator (insulator) 1130, and the negative electrodes 1110, the separator 1130, and the positive electrodes 1120 may be folded multiple times in a zigzag form, for example.

The negative electrodes 1110 may be arranged on one side of the separator 1130, and the first collector tabs 1111 may be connected to non-coated portions of the negative electrodes 1110. The first collector tabs 1111 may be respectively connected to the negative electrodes 1110. The first collector tabs 1111 may be connected to a first electrode lead 131 by a collector module 710 (described below).

The positive electrodes 1120 may be arranged on an opposite side of the separator 1130 at positions opposite to the negative electrodes 1110 with the separator 1130 therebetween.

The positive electrodes 1120 may be formed in a quadrangular shape, e.g., rectangular shape through a stamping process and may be arranged on an opposite side of the separator 1130. Although the positive electrodes 1120 are illustrated as having a quadrangular shape, e.g., rectangular shape, the disclosure is not limited thereto. The second electrodes 1120 may have various shapes such as partially rounded shapes.

The positive electrodes 1120 may be arranged apart from each other on an opposite side of the separator 1130, and the second collector tabs 1121 may be connected to edges of the second electrodes 1120 in a state in which the second collector tabs 1121 protrude from the edges of the second electrodes 1120. The second collector tabs 1121 may be respectively connected to the positive electrodes 1120. The second collector tabs 1121 may be connected to a second electrode lead 132 by the collector module 710 (described below).

The number of the at least one battery cell 110 of the battery 100 and a connection method of the at least one battery cell 110 may be determined based on desired levels of power and voltage of the battery pack 10. For conceptual purposes only, FIG. 1 shows that the at least one battery cell 110 of the battery 100 is connected in series to each other. However, the at least one battery cell 110 may be connected in series, parallel, or series-parallel to each other. For conceptual purposes only, FIG. 1 shows that the battery pack 10 includes one battery 100. However, the battery pack 10 may include a plurality of batteries 100 connected in series, parallel, or series-parallel to each other. The battery 100 may include only one battery cell 110.

The battery 100 may be implemented as a battery module including a plurality of battery cells 110. The battery 100 includes a pair of terminals 101 and 102 to which an electric load or a charging device may be connected.

In the specification, the battery in the expression “the charging state of a battery” or “battery charging state” may refer to the battery 100 or each of the at least one battery cell 110 of the battery 100. Although the specification describes a method of determining the charging state of the battery 100 including the at least one battery cell 110, the idea of the specification may equally apply to a method of determining the charging state of a battery including a single battery cell.

In an embodiment, the battery pack 10 may include a switch. The switch may be connected between the battery 100 and one of the terminals 101 and 102. The switch may be controlled by a processor 200. Although not shown in FIG. 1, the battery pack 10 may further include a battery protection circuit, a fuse, a current sensor, or the like.

In an embodiment, the battery charging state determination apparatus 20 may include the processor 200 and a memory (e.g., non-transitory recording medium) 300.

The processor 200 may control the overall operation of the battery charging state determination apparatus 20. In an embodiment, to this end, the processor 200 may selectively include devices such as processors, application-specific integrated circuits (“ASICs”), other chipsets, logic circuits, registers, communication modems, and/or data processing devices that are known in the art, for example.

The processor 200 may perform basic arithmetic, logic, and input/output (“I/O”) operations. In an embodiment, the processor 200 may execute program code stored in the memory 300, for example. The processor 200 may store data in the memory 300 or load data stored in the memory 300.

The memory 300 may be a storage medium that is readable by the processor 200 and includes a nonvolatile mass storage device such as random access memory (“RAM”), read only memory (“ROM”), and a disk drive. The memory 300 may store an operating system (“OS”) and at least one program or application code. In an embodiment, the memory 300 may store program code for determining the charging state of the battery 100 during charging. The memory 300 may store data obtained by measuring at least one parameter of the battery 100 during charging. In an embodiment, the data may include the charge/discharge current, the terminal voltage, and/or the temperature of the battery 100, for example.

The memory 300 may store program code for determining the charging state of the battery 100 using data obtained by measuring at least one parameter of the battery 100. The at least one parameter of the battery 100 refers to a component or variable such as the terminal voltage of the battery 100, the charge/discharge current of the battery 100, and/or ambient temperature.

The battery charging state determination apparatus 20 may further include a voltage measuring unit 400, a current measuring unit 500, and a temperature measuring unit 600 to measure at least one parameter of the battery 100. The battery charging state determination apparatus 20 may further include a communication module (not shown) for communication with other devices, such as an electronic control unit of a vehicle or a controller of a charging device.

The voltage measuring unit 400 may measure the voltage of the battery 100. In an embodiment, as shown in the configuration of FIG. 1, the voltage measuring unit 400 may be electrically connected to opposite ends of the battery 100 and/or the at least one battery cell 110, for example. In addition, the voltage measuring unit 400 may be electrically connected to the processor 200 to transmit and receive electrical signals. Furthermore, under control by the processor 200, the voltage measuring unit 400 may measure voltage between the opposite ends of the battery 100 and/or the at least one battery cell 110 at intervals and may output a signal representing the magnitude of the measured voltage to the processor 200. In this case, the processor 200 may determine the voltage of the battery 100 and/or the at least one battery cell 110 based on the signal output by the voltage measuring unit 400. In an embodiment, the voltage measuring unit 400 may be implemented using a voltage measuring circuit that is commonly used in the art, for example.

In addition, the current measuring unit 500 may measure the current of the battery 100. In an embodiment, as shown in the configuration of FIG. 1, the current measuring unit 500 may be electrically connected to a current sensor provided in a charge/discharge path of the battery 100 and/or the at least one battery cell 110, for example. Furthermore, the current measuring unit 500 may be electrically connected to the processor 200 to transmit and receive electrical signals. In addition, under control by the processor 200, the current measuring unit 500 may repeatedly measure the magnitude of charge or discharge current of the battery 100 and/or the at least one battery cell 110 at given intervals and may output a signal representing the magnitude of measured current to the processor 200. In this case, the processor 200 may determine the magnitude of current based on the signal output from the current measuring unit 500. In an embodiment, the current sensor may be implemented using a Hall sensor or a sensing resistor that is commonly used in the art, for example.

The temperature measuring unit 600 may measure the temperature of the battery 100. In an embodiment, as shown in the configuration of FIG. 1, the temperature measuring unit 600 may be connected to the battery 100 and/or the at least one battery cell 110 to measure the temperature of a secondary battery provided in the battery 100 and/or the at least one battery cell 110, for example. Furthermore, the temperature measuring unit 600 may be electrically connected to the processor 200 to transmit and receive electrical signals. In addition, the temperature measuring unit 600 may repeatedly measure the temperature of the secondary battery at given intervals and may output a signal representing the magnitude of measured temperature to the processor 200. In this case, the processor 200 may determine the temperature of the secondary battery based on the signal output from the temperature measuring unit 600. In an embodiment, the temperature measuring unit 600 may be implemented using a thermocouple that is commonly used in the art, for example.

In addition, the processor 200 may estimate the state of charge (“SOC”) of the battery 100 by at least one selected from voltage values, current values, and temperature values of the battery 100 that are measured by the voltage measuring unit 400, the current measuring unit 500, and the temperature measuring unit 600 and are transmitted to the processor 200. Here, the term “SOC” is a parameter representing the charging state of the battery 100. SOC indicates how much energy is stored in the battery 100 and may be expressed as a percentage ranging from 0% to 100%. In an embodiment, an SOC of 0% may refer to a fully discharged state, and an SOC of 100% may refer to a fully charged state, for example. However, this expression method may be variously defined according to design intent or embodiments. Various techniques may be employed to estimate or measure the SOC of the battery 100.

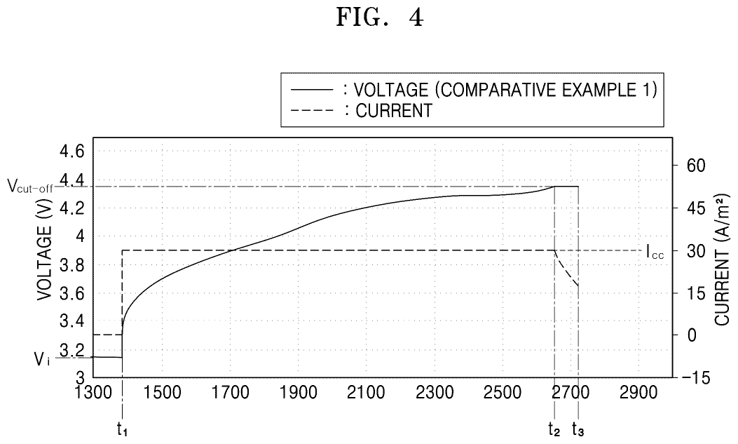

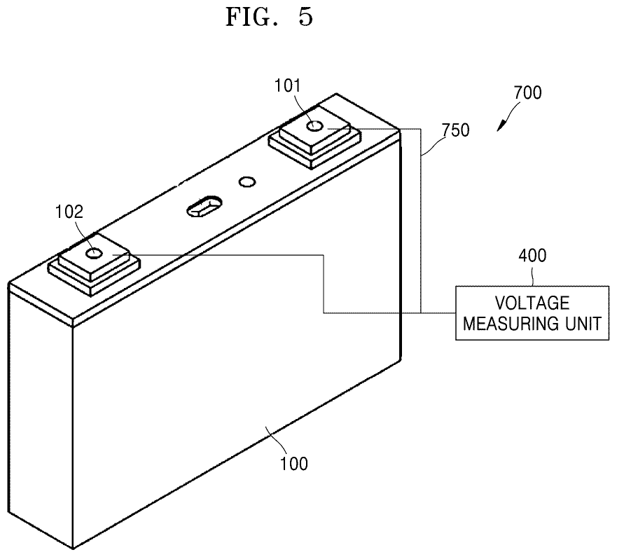

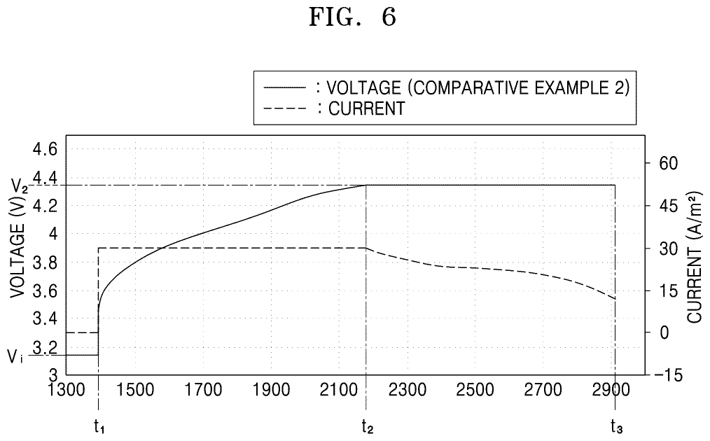

FIG. 4 is a graph illustrating current and voltage profiles during constant-current charging and constant-voltage charging according to Comparative Example 1. FIG. 5 is a diagram schematically illustrating the battery 100 and the voltage measuring unit 400. FIG. 6 is a graph illustrating current and voltage profiles during constant-current charging and constant-voltage charging according to Comparative Example 2.

Referring to FIGS. 1 to 4, in an embodiment, the processor 200 may estimate the SOC of the battery 100 by at least one parameter of the battery 100 as described above, and may estimate a first resistance of the battery 100 by the at least one parameter of the battery 100. In an embodiment, the first resistance of the battery 100 may include at least one selected from resistance caused by the electrochemical behavior of the battery 100 and/or the at least one battery cell 110, and sheet resistance of the negative electrodes 1110 and the positive electrodes 1120 that are stacked in a plurality of layers.

In an embodiment, the processor 200 may charge the battery 100 in a constant-current charging mode (“CC mode”) by the SOC, the first resistance, and the at least one parameter of the battery 100, and may then charge the battery 100 in a constant-voltage charging mode (“CV mode”) by the SOC, the first resistance, and the at least one parameter of the battery 100.

In an embodiment, in the CC mode, the battery 100 is charged with a constant current. In Comparative Example 1, as shown in FIG. 4, a terminal voltage V_{cc} of the battery 100 may rise in the CC mode from an initial voltage Vi, at which charging begins, to a charging voltage V_{cut-off}. The charging voltage V_{cut-off}, up to which the terminal voltage V_{cc} of the battery 100 rises, may be a cut-off voltage V_{cut-off} predetermined by the first resistance of the battery 100. In an embodiment, the cut-off voltage V_{cut-off} shown in FIG. 4 may be 4.35 volts (V). In the CC mode, a constant current I_{cc} may flow as a charging current in the battery 100, for example. In an embodiment, the constant current I_{cc} shown in FIG. 4 may be 30 amperes per square meter (A/m²). In this case, a time period from a time point t₁ to a time point t₂ is the duration of the CC mode, for example.

Furthermore, in the CV mode, the battery 100 is charged with a constant voltage. As shown in FIG. 4, in the CV mode, the terminal voltage V_{cc} of the battery 100 is maintained at a constant level equal to the cut-off voltage V_{cut-off}, and charging current may decrease. In this case, a time period from a time point t₂ to a time point t₃ is the duration of the CV mode.

In an embodiment, in Comparative Example 1, the battery 100 may have a rated charging capacity of 15 Ah and may be charged with a charging rate (C-rate) of 2C to increase the SOC of the battery 100 from 10% to 80% through the CC mode and the CV mode, for example. In this case, the time period from a time point t₁ to a time point t₂, which is the charging duration in the CC mode, is 1272 seconds. In addition, the time period from a time point t₂ to a time point t₃, which is the charging duration in the CV mode, is 67 seconds. In Comparative Example 1, the SOC of the battery 100 may increase from 10% to 80% through the CC mode and the CV mode. However, the disclosure is not limited thereto, and the SOC of the battery 100 may increase from 0% to 100% through the CC mode and CV mode, depending on charging settings.

As described above, the voltage measuring unit 400 may be electrically connected to the battery 100 and/or the at least one battery cell 110 to measure the voltage of the battery 100 for estimating the SOC of the battery 100 by at least one parameter of the battery 100. A connection module 700 may be disposed between the battery 100 and the voltage measuring unit 400 to electrically connect the battery 100 and the voltage measuring unit 400 to each other.

Referring to FIGS. 2, 3, and 5, when the battery 100 includes a plurality of battery cells 110, the connection module 700 may include the collector module 710 that electrically connects the battery cells 110 to each other, and a connection member 750 that is disposed between the battery 100 and the voltage measuring unit 400 to electrically connect the battery 100 and the voltage measuring unit 400 to each other.

In an embodiment, the collector module 710 may include any connection device capable of electrically collecting electrodes of the battery cells 110. In an embodiment, the negative electrodes 1110 may be disposed on one side of the separator 1130, and the first collector tabs 1111 may be connected to the non-coated portions of the negative electrodes 1110, for example. The first collector tabs 1111 may be connected to the negative electrodes 1110, respectively. The first collector tabs 1111 may be connected to each other by the collector module 710, e.g., by first collector modules 711. Thus, the first collector tabs 1111 may be connected to the first electrode lead 131, allowing current to flow through the first collector tabs 1111.

In addition, in an embodiment, the second collector tab 1121 may be connected to edges of the positive electrodes 1120 and may protrude from the edges of the positive electrodes 1120. The second collector tabs 1121 may be connected to each other by the collector module 710, e.g., by second collector modules 712. Thus, the second collector tabs 1121 may be connected to the second electrode lead 132, allowing current to flow through the second collector tabs 1121.

In the example described above, plate-shaped collector members capable of electrically connecting the first and second collector tabs 1111 and 1121 are described as embodiments of the collector module 710 capable of electrically collecting the battery cells 110 to each other. However, the disclosure is not limited thereto. In other examples, the collector module 710 may include any collector members capable of electrically collecting the battery cells 110 to each other.

As described above, when the battery cells 110 are electrically connected to each other by the collector module 710, the first electrode lead 131 and the second electrode lead 132 may be electrically connected to the pair of terminals 101 and 102 provided on the battery 100. In an embodiment, the connection member 750 may be disposed between the battery 100 and the voltage measuring unit 400 to transmit information about the voltages of the battery cells 110 to the voltage measuring unit 400. In an embodiment, the battery cells 110 may be electrically connected to each other by the collector module 710, and the first electrode lead 131 and the second electrode lead 132 may be electrically connected to the pair of terminals 101 and 102 provided on the battery 100, for example. In this case, the connection member 750 may be disposed between the voltage measuring unit 400 and the pair of terminals 101 and 102 to electrically connect the battery 100 and the voltage measuring unit 400 to each other. Thus, the voltage measuring unit 400 may measure information about the voltages of the battery cells 110.

As described above, when the connection module 700 is disposed between the battery 100 and the voltage measuring unit 400, a second resistance may be generated by the connection module 700. In an embodiment, when the connection module 700 includes the collector module 710 or the connection member 750, resistance may be generated by the collector module 710 or the connection member 750, for example. In addition, resistance such as contact resistance may also be generated due to contact of the collector module 710 or the connection member 750.

In an embodiment, the second resistance generated by the connection module 700 may be pre-calculated and stored in the memory 300. In an embodiment, the second resistance generated by the connection module 700 may be pre-measured using a resistance measurement module that is commonly used in the art, for example. In an embodiment, during a process of determining the second resistance generated by the connection module 700, the second resistance may vary depending on the shape, placement, and contact state of the connection module 700. When calculating a compensation voltage, the second resistance generated by the connection module 700 may be adjusted to prevent overcharging.

In an embodiment, as shown in FIG. 2, when the collector module 710 connects the first and second collector tabs 1111 and 1121 to the first and electrode leads 131 and 132, the length of the collector module 710 may vary depending on the positions of the first and second collector tabs 1111 and 1121, for example. When the length of the collector module 710 varies, the resistance of the collector module 710 may also vary according to the length of the collector module 710 In an embodiment, the length of a 1st-1 collector module 7111 that is uppermost among the first collector modules 711 may be greater than the length of a 1st-2 collector module 7112 that is lowermost among the first collector modules 711, for example. In this case, the resistance of the 1st-1 collector module 7111 may be greater than the resistance of the 1st-2 collector module 7112.

In an embodiment, when the battery cells 110 are connected in parallel to the voltage measuring unit 400, and the first collector modules 711 have different resistances, excessive compensation voltages may be set for some of the battery cells 110 (described below), and thus, overcharging may occur. When the second resistance is determined for calculating the compensation voltage, the average resistance of the first collector modules 711 may be set as a representative resistance and may be used as the second resistance to prevent overcharging.

In addition, when determining the second resistance for calculating the compensation voltage, the resistance of a first collector module 711 that is lowest among the resistances of the first collector modules 711 may be set as a representative resistance and may be used as the second resistance. However, the disclosure is not limited thereto, and the second resistance may be determined differently depending on the SOC of the battery 100 and the shape, placement, and contact state of the connection module 700.

In an embodiment, when the connection module 700 includes the collector module 710 connecting the first collector tabs 1111 to each other and the second collector tabs 1121 to each other, and the connection member 750 connecting the battery 100 and the voltage measuring unit 400 to each other, the second resistance generated by the collector module 710 may range from about 0.1 milliohm (m (2) to about 5 mΩ, for example. In addition, the second resistance generated by the connection member 750 may range from about 0.01 mΩ to about 5 mΩ. In this case, the total resistance of the connection module 700 may be determined by the sum of the second resistance caused by the collector module 710 and the second resistance caused by the connection member 750.

In the example described above, it is described that the second resistance caused by the connection module 700 includes the inherent resistance of the connection module 700 and the contact resistance of the connection module 700. However, the disclosure is not limited thereto. Other resistances between the battery 100 and the voltage measuring unit 400, excluding the first resistance of the battery 100, may also be defined as the second resistance and stored in the memory 300.

According to Comparative Example 2, when the second resistance is generated by the connection module 700 in addition to the first resistance of the battery 100, charging may be performed with a constant current in a CC mode. In this case, the terminal voltage of the battery 100 may increase from an initial voltage Vi, at which the charging begins, to a charging voltage V₂, as shown in FIG. 6. The charging voltage V₂ may drop due to the second resistance caused by the connection module 700. In an embodiment, in Comparative Example 2 shown in FIG. 6, the second resistance caused by the connection module 700 may be 4 mΩ. In this case, the second resistance may be pre-calculated and stored in the memory 300. Due to the addition of the second resistance caused by the connection module 700, the terminal voltage of the battery 100, that is, the charging voltage V₂, may be less than a cutoff voltage V_{cut-off} determined by the first resistance of the battery 100. In this case, the duration of the CC mode from a time point t₁ to a time point t₂ may be 778 seconds, which may be less than that in Comparative Example 1.

Furthermore, in a CV mode, the battery 100 may be charged while the terminal voltage of the battery 100 is maintained constant. As shown in FIG. 6, in the CV mode, the terminal voltage of the battery 100 may be maintained constant at the charging voltage V₂ that is less than the cutoff voltage V_{cut-off}, and charging current may decrease with time. When considering the point at which the SOC of the battery 100 rises to 80%, the duration of the CV mode from a time point t₂ to a time point t₃ is 728 seconds, which may be greater than that in Comparative Example 1.

Therefore, when the second resistance is generated by the connection module 700 in addition to the first resistance of the battery 100, the total charging duration from a time point t₁ to a time point t₃, during which the SOC of the battery 100 rises from 10% to 80%, may be 1516 seconds, which is greater than 1339 seconds in Comparative Example 1 in which only the first resistance of the battery 100 is considered. In other words, it may be confirmed that the total charging duration increases when the voltage measuring unit 400 is connected to measure the voltage of the battery 100, that is, a parameter of the battery 100 during charging.

The following description concerns a method of determining the charging state of the battery 100 during charging for monitoring the state of the battery 100 and applying a compensation voltage to optimize the charging duration of the battery 100 by compensating for a voltage drop caused by a second resistance.

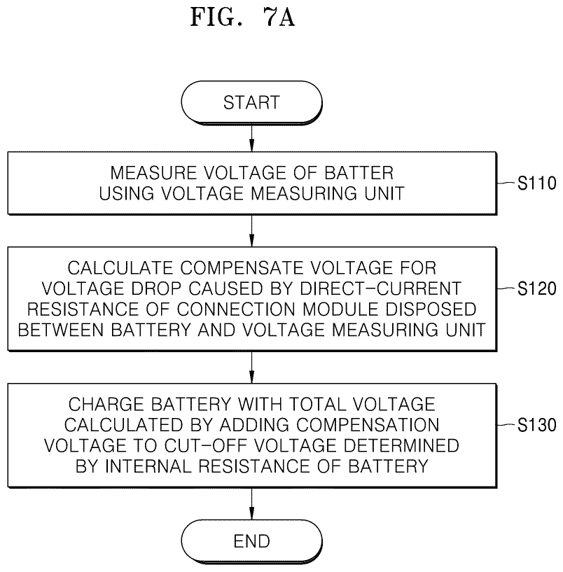

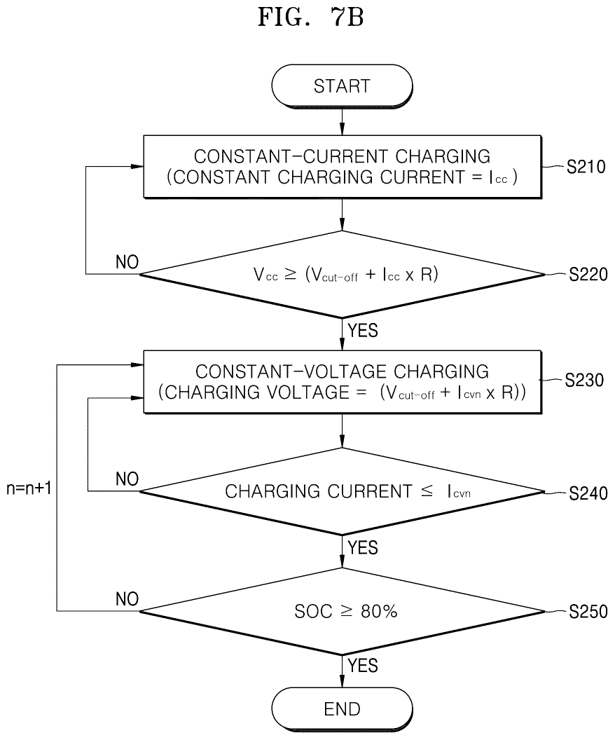

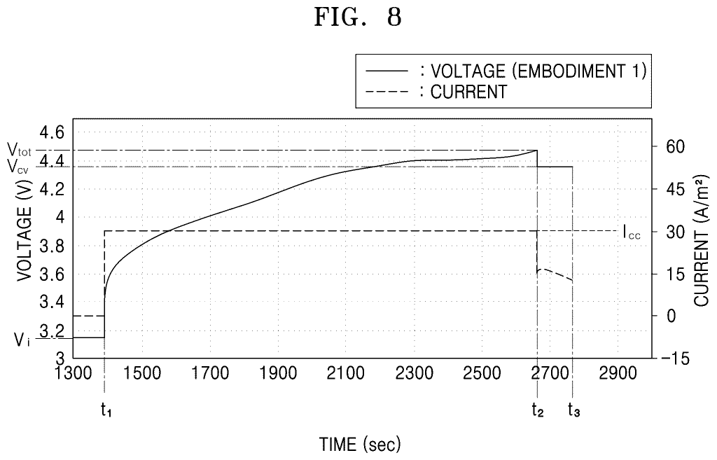

FIG. 7A is a flowchart illustrating an embodiment of a method of determining a battery charging state. FIG. 7B is a flowchart illustrating an embodiment of a method of determining a battery charging state. FIG. 8 is a graph illustrating current and voltage profiles during constant-current charging and constant-voltage charging according to Embodiment 1.

Referring to FIG. 7A, in an embodiment, the method of determining a battery charging state may include measuring the voltage of the battery 100 by the voltage measuring unit 400 (S110). In an embodiment, the voltage measuring unit 400 may measure information about the voltages of the battery cells 110 during a process of charging the battery 100, for example. In this case, the connection module 700 may be disposed between the battery 100 and the voltage measuring unit 400, and a second resistance R may be generated due to the connection module 700.

Next, a compensation voltage V_{com} may be calculated to compensate for a voltage drop caused by the second resistance R of the connection module 700 disposed between the battery 100 and the voltage measuring unit 400 (S120). In an embodiment, as shown in FIG. 5, when the collector module 710 and the connection member 750 are disposed between the battery 100 and the voltage measuring unit 400, the second resistance R may be determined by the sum of resistance generated by the collector module 710 and resistance generated by the connection member 750, for example.

In an embodiment, the connection module 700 disposed between the battery 100 and the voltage measuring unit 400 may be pre-checked in a design stage. Therefore, the second resistance R generated by the connection module 700 may be pre-measured and stored in the memory 300.

The processor 200 may calculate the compensation voltage V_{com} using the second resistance R of the connection module 700 stored in the memory 300 and a charging current I flowing in the battery 100. In an embodiment, in a CC mode, the compensation voltage V_{com} may be determined using the second resistance R and a constant current I_{cc} as shown by Equation 1 below, for example.

$${V}_{com} = {I}_{c c} \times R \qquad Equation 1$$

Additionally, in a CV mode, the compensation voltage V_{com} may be determined using the second resistance R and a constant-voltage charging current I_{cv}. as shown by Equation 2 below.

$${V}_{com} = {I}_{c v} \times R \qquad Equation 2$$

Next, the method of determining a battery charging state may include charging the battery 100 based on a total voltage Vₜₒₜ that is the sum of the compensation voltage V_{com} and a cutoff voltage V_{cut-off} that is determined by the first resistance of the battery 100 (S130). In an embodiment, the processor 200 may calculate the total voltage Vₜₒₜ by summing the compensation voltage V_{com} and the cutoff voltage V_{cut-off} that is determined by the first resistance of the battery 100.

In the CC mode, the processor 200 may determine the total voltage Vₜₒₜ by summing the cutoff voltage V_{cut-off} and the compensation voltage V_{com}, as shown in Equation 3 below.

$${V}_{tot} = {V}_{cut - off} + {I}_{cc} \times R \qquad Equation 3$$

Referring to FIGS. 7B and 8, in Embodiment 1, the battery 100 is charged with a constant current I_{cc} in a CC mode (S210). In this case, a terminal voltage V_{cc} of the battery 100 may increase from an initial voltage Vi at the start of charging to a total voltage Vₜₒₜ. The total voltage Vₜₒₜ may additionally include a compensation voltage V_{com} to account for a voltage drop that may occur due to the connection module 700. Therefore, the total voltage Vₜₒₜ may be greater than a cutoff voltage V_{cut-off} determined by the first resistance of the battery 100. In this case, it may be confirmed that the charging duration of the CC mode from a time point t₁ to a time point t₂ is 1268 seconds and is substantially the same as that in Comparative Example 1.

However, when the compensation voltage V_{com} is not applied in a CV mode, the terminal voltage V_{cc} of the battery 100 is maintained at a constant voltage V_{cv} less than the cutoff voltage V_{cut-off}, and charging current may decrease with time. Considering the point at which the SOC of the battery 100 rises to 80%, the duration of the CV mode from a time point t₂ to a time point t₃ is 102 seconds, which is greater than that in Comparative Example 1.

Therefore, it may be confirmed that the total charging duration of the battery 100 from a time point t₁ to a time point t₃ in Embodiment 1 is 1370 seconds, which is less than 1516 seconds in Comparative Example 2 shown in FIG. 6 but greater than 1339 seconds in Comparative Example 1 shown in FIG. 3. In other words, it may be confirmed that the total charging duration reduces compared to Comparative Example 2 in which the compensation voltage V_{com} is applied in the CC mode and the connection module 700 is disposed, but slightly increases compared to Comparative Example 1 in which the connection module 700 is not disposed.

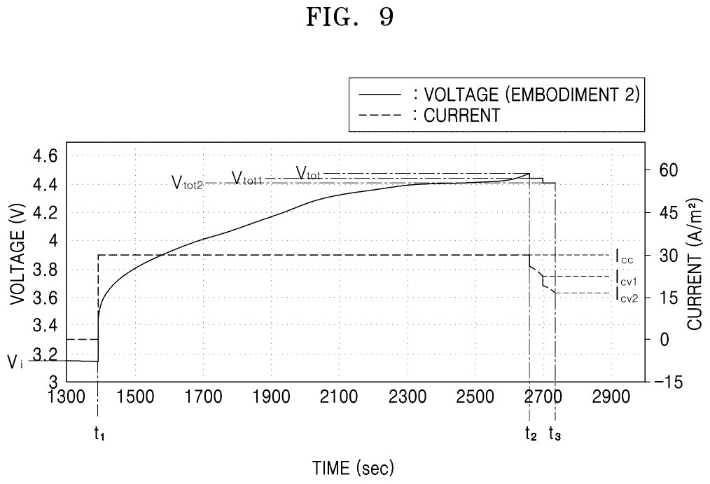

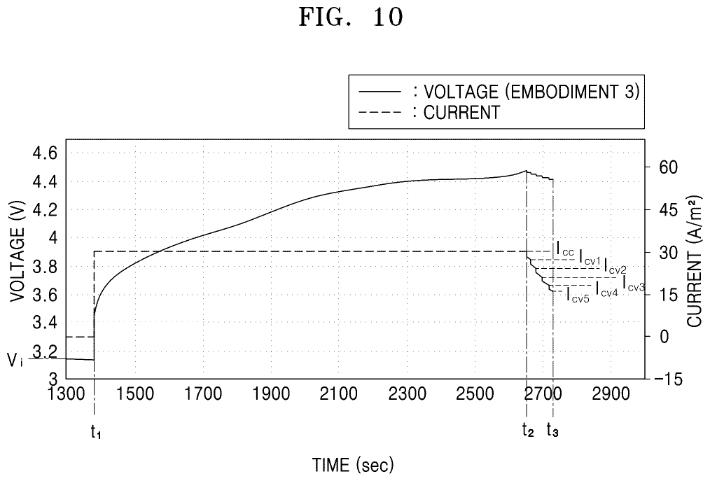

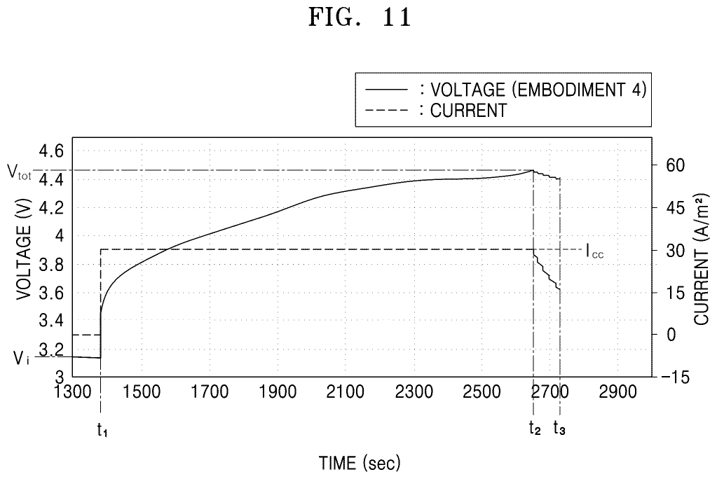

FIG. 9 is a graph illustrating current and voltage profiles during constant-current charging and constant-voltage charging according to Embodiment 2. FIG. 10 is a graph illustrating current and voltage profiles during constant-current charging and constant-voltage charging according to Embodiment 3. FIG. 11 is a graph illustrating current and voltage profiles during constant-current charging and constant-voltage charging according to Embodiment 4.

In an embodiment, after transition from the CC mode to the CV mode, the charging current I_{cv} in the CV mode may sequentially decrease from the constant current I_{cc}, for example. As the charging current I_{cv} decreases in the CV mode, the total voltage Vₜₒₜ, which is the sum of the cutoff voltage V_{cut-off} and the compensation voltage V_{com}, may vary with time.

In an embodiment, in the CV mode, the processor 200 may determine the total voltage Vₜₒₜ by summing the cutoff voltage V_{cut-off} and the compensation voltage V_{com} as shown in Equation 4 below, for example.

$${V}_{tot} = {V}_{cut - off} + {I}_{cv} \times R \qquad Equation 4$$

As described above, the charging current lev in the CV mode may decrease with time. Therefore, it may be desired to monitor the charging current I_{cv} with time in the CV mode.

In an embodiment, the method of determining a battery charging state may include measuring the current of the battery 100 by the current measuring unit 500 in the CV mode. Therefore, in the CV mode, the compensation voltage V_{com} may be determined by the product of the second resistance R and the charging current I_{cv} measured by the current measuring unit 500.

However, considering the computational performance of the processor 200, it may be difficult to determine the compensation voltage V_{com} while reflecting, in real time, the charging current I_{cv} measured by the current measuring unit 500. In an embodiment, considering the computational performance of the processor 200, the charging current I_{cv} in the CV mode may be divided into n steps (n is a natural number greater than 1), and accordingly, the compensation voltage V_{com} may also be determined differently in the n steps. In an embodiment, the compensation voltage V_{com} may be determined by the product of a pre-set charging current I_{cv} and the second resistance R in each of the n steps, for example.

Referring to FIGS. 7B and 9, in Embodiment 2, the charging current lev may be divided into n steps, e.g., two steps. In addition, constant-voltage charging may be performed with different voltages respectively in the steps. The memory 300 may store a first charging current I_{cv1} and a second charging current I_{cv2} that are pre-set for constant-voltage charging. Charging current may be set to sequentially decrease to the first charging current I_{cv1} and the second charging current I_{cv2} at predetermined intervals. In an embodiment, when the constant current I_{cc} is 30 A/m², charging current may decrease by 25% of the constant current I_{cc} in each step such that the first charging current I_{cv1} may be 22.5 A/m², and the second charging current I_{cv2} may be 15 A/m², for example.

When the terminal voltage V_{cc} of the battery 100 rises from the initial voltage Vi at the start of charging to the total voltage Vₜₒₜ in the CC mode, the mode of charging may transition from the CC mode to the CV mode (S220).

As the mode of charging transitions from the CC mode to the CV mode, the charging current I_{cv} may decrease from the constant current I_{cc} of 30 A/m². A first constant-voltage charging step may proceed until the charging current of the battery 100 measured by the current measuring unit 500 reaches the first charging current I_{cv1}, e.g., 22.5 A/m², which is less than the constant current I_{cc} (S230) In the first constant-voltage charging step of the CV mode, a first total voltage Vₜₒₜ₁ may be calculated as follows.

$${V}_{tot 1} = {V}_{cut - off} + {I}_{cv 1} \times R$$

In this case, the compensation voltage V_{com} may be determined by the product of the first charging current I_{cv1} and the second resistance R.

In the first constant-voltage charging step of the CV mode, the charging current I_{cv} may sequentially decrease from the constant current I_{cc} to the first charging current I_{cv1} that is predetermined. In an embodiment, the compensation voltage V_{com} may be determined based on the predetermined first charging current I_{cv1} in the first constant-voltage charging step of the CV mode to prevent accidents caused by overcharging the battery 100.

As the charging current of the battery 100 measured by the current measuring unit 500 reaches the first charging current I_{cv1}, e.g., 22.5 A/m², a second constant-voltage charging step may proceed (S240). In the second constant-voltage charging step of the CV mode, a second total voltage Vₜₒₜ₂ may be calculated as follows.

$${V}_{tot 2} = {V}_{cut - off} + {I}_{cv 2} \times R$$

In this case, the compensation voltage V_{com} may be determined by the product of the second resistance R and the second charging current I_{cv2} to which the charging current of the battery 100 is set to sequentially decrease. The charging current of the battery 100 measured by the current measuring unit 500 may decrease from the first charging current I_{cv1} to the second charging current I_{cv2}. The multistep CV mode of Embodiment 2 may proceed until the SOC of the battery 100 reaches a specified SOC, e.g., an SOC of 80% (S250). According to Embodiment 2, the CC mode lasts for 1269 seconds, and the CV mode lasts for 75 seconds, confirming a total charging duration of 1344 seconds.

Considering enhancing the computational performance of the processor 200, the multiple steps of the CV mode may be further divided. Referring to FIGS. 7B and 10, the charging current I_{cv} in Embodiment 3 may be divided into five steps (n=5) to perform constant-voltage charging with different voltages respectively in the five steps. The memory 300 may pre-store first to fifth charging currents I_{cv1} to I_{cv}5 to which the charging current I_{cv} may sequentially decrease in the CV mode. The charging current I_{cv} may be set to sequentially decrease to the first charging current I_{cv1} to the fifth charging current I_{cv}5 at predetermined intervals. In an embodiment, when the constant current I_{cc} is 30 A/m², the charging current I_{cv} may reduce by 10% of the constant current I_{cc} in each step such that the first charging current I_{cv1} may be 27 A/m², the second charging current I_{cv2} may be 24 A/m², the third charging current I_{cv}3 may be 21 A/m², the fourth charging current I_{cv}4 may be 18 A/m², and the fifth charging current I_{cv}5 may be 15 A/m², for example. Although Embodiments 2 and 3 divide the CV mode into two steps and five steps, respectively, the disclosure is not limited thereto. In an embodiment, any number of steps may be defined in the same manner, and multistep constant-voltage charging may continue until the SOC of the battery 100 reaches an input target value.

As the CC mode transitions to the CV mode, the charging current of the battery 100 may decrease from the constant current I_{cc} of 30 A/m². As the charging current of the battery 100 measured by the current measuring unit 500 sequentially reaches the first charging current I_{cv1} to the fifth charging current I_{cv}5, first to fifth steps of the CV mode may proceed with different constant voltages. The total voltage Vₜₒₜ determined by considering the compensation voltage V_{com} is substantially the same as that described in Equation 4 and Embodiment 2, and thus, a description thereof is omitted here. The multistep CV mode of Embodiment 3 may proceed until the SOC of the battery 100 reaches a specified SOC, e.g., an SOC of 80%. According to Embodiment 3, the CC mode lasts for 1271 seconds, and the CV mode lasts for 75 seconds, confirming a total charging duration of 1346 seconds.

Considering enhancing the computational performance of the processor 200, the multiple steps of the CV mode may be further divided to reflect variations in charging current in real-time. Referring to FIGS. 7B and 11, in Embodiment 4, the charging current I_{cv} in the CV mode may sequentially decrease from the constant current I_{cc}. The current measuring unit 500 may measure the charging current I_{cv} that sequentially decreases, and the processor 200 may adjust charging voltage in real-time by reflecting the measured charging current lev. In this case, the total voltage Vₜₒₜ determined by considering the compensation voltage V_{com} may be determined as the charging voltage. The method of determining the total voltage Vₜₒₜ by considering the compensation voltage V_{com} is substantially the same as that described in equation 4 and Embodiment 2, and a description thereof is omitted here. The CV mode in Embodiment 4 may proceed until the SOC of the battery 100 reaches a specified SOC, e.g., an SOC of 80%. According to Embodiment 4, the CC mode lasts for 1272 seconds, and the CV mode lasts for 75 seconds, confirming a total charging duration of 1347 seconds.

Therefore, it may be confirmed that the total charging duration of the battery 100 in Embodiment 4 is less than 1516 seconds in Comparative Example 2. In addition, it may be confirmed that the total charging duration of the battery 100 in Embodiment 4 is less than that (1370 seconds) in Embodiment 1. In other words, it may be confirmed that owing to the application of the compensation voltage V_{com} in both the CC mode and the CV mode, the total charging duration decreases to be similar to the charging duration in Comparative Example 1.

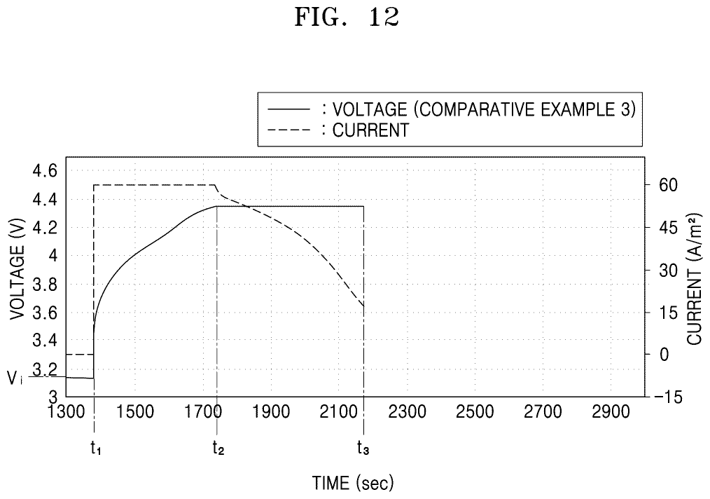

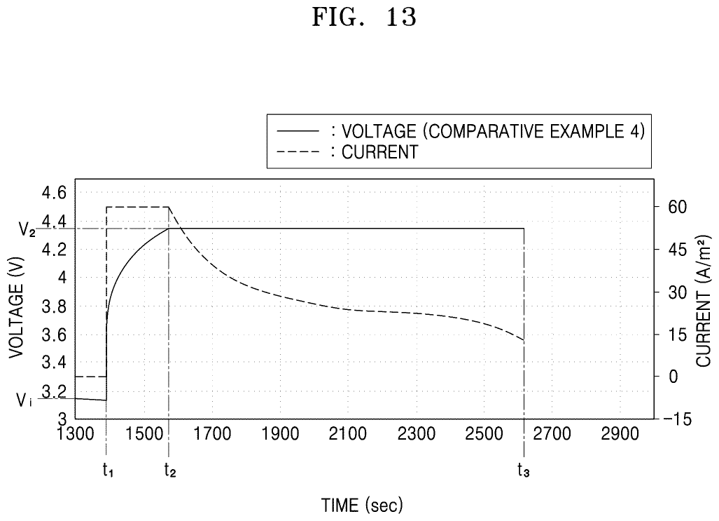

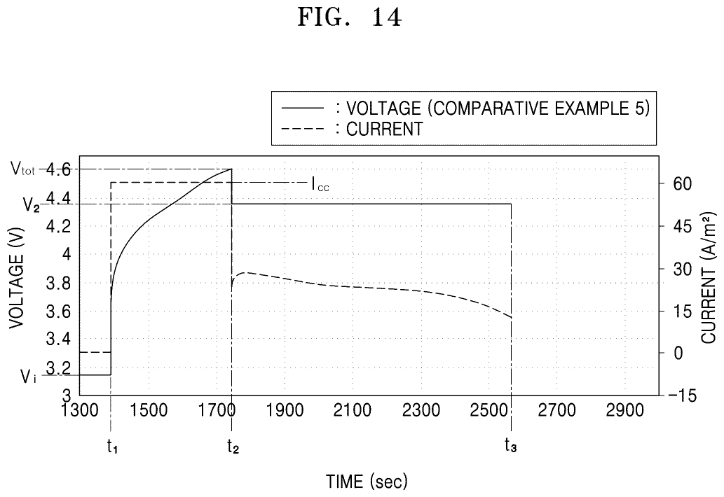

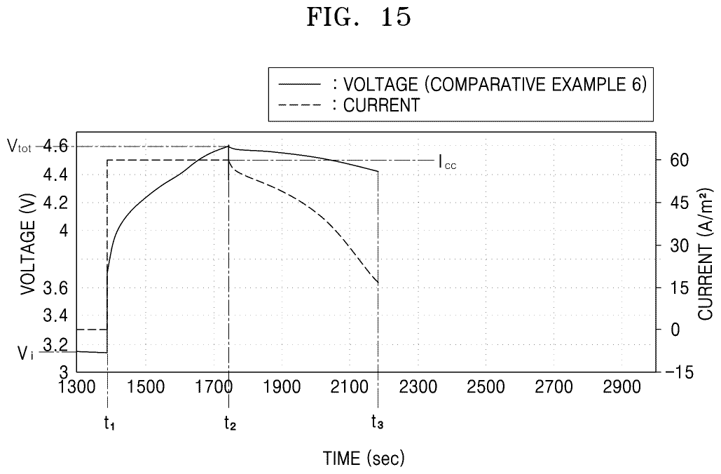

FIG. 12 is a graph illustrating current and voltage profiles during constant-current charging and constant-voltage charging according to Comparative Example 3. FIG. 13 is a graph illustrating current and voltage profiles during constant-current charging and constant-voltage charging according to Comparative Example 4. FIG. 14 is a graph illustrating current and voltage profiles during constant-current charging and constant-voltage charging according to Embodiment 5. FIG. 15 is a graph illustrating current and voltage profiles during constant-current charging and constant-voltage charging according to Embodiment 6.

As described above, in Comparative Example 1, the C-rate of the battery 100 is 2C, and the constant current I_{cc} in the CC mode is 30 A/m². However, referring to FIG. 12, in Comparative Example 3, the C-rate of the battery 100 is 4C, and the constant current I_{cc} in the CC mode is 60 A/m². Conditions other than the C-rate and the constant current I_{cc} are substantially the same as those in Comparative Example 1, and thus, descriptions thereof are omitted here.

In Comparative Example 3, the SOC of the battery 100 may rise from 0% to 80% in the CC mode and the CV mode. In this case, it may be conformed that the duration from a time point t₁ to a time point t₂ in the CC mode is 356 seconds. Additionally, it may be conformed that the duration from a time point t₂ to a time point t₃ in the CV mode is 436 seconds.

In Comparative Example 4, a second resistance may be generated by the connection module 700 in addition to the first resistance of the battery 100. In an embodiment, in Comparative Example 4 shown in FIG. 13, the second resistance generated by the connection module 700 may be 4 mΩ, for example. In this case, the second resistance may be pre-calculated and stored in the memory 300. Due to the addition of the second resistance of the connection module 700, a charging voltage V₂ may be less than a cutoff voltage V_{cut-off} determined by the first resistance of the battery 100. In this case, it is confirmed that the duration of the CC mode from a time point t₁ to a time point t₂ is 182 seconds, which is shorter than that in Comparative Example 3.

Furthermore, in the CV mode, the terminal voltage of the battery 100 may be maintained at a constant voltage V₂ less than the cutoff voltage V_{cut-off}, and charging current may decrease with time. When considering the point at which the SOC of the battery 100 rises to 80%, the duration of the CV mode from a time point t₂ to a time point t₃ is confirmed to be 1043 seconds, which is greater than that in Comparative Example 3.

Therefore, in Comparative Example 4, the total charging duration of the battery 100 (from a time point t₁ to a time point t₃) during which the SOC of the battery 100 rises from 10% to 80% is confirmed to be 1225 seconds, which is greater than 792 seconds in Comparative Example 3. In other words, it may be confirmed that the total charging duration increases due to a parameter of the battery 100 during charging, that is, the connection module 700 that is disposed to connect the battery 100 and the voltage measuring unit 400 to each other for measuring the voltage of the battery 100.

Referring to FIG. 14, in Embodiment 5, the battery 100 is charged with a constant current I_{cc} in the CC mode. In this case, the terminal voltage of the battery 100 may increase to a total voltage Vₜₒₜ from an initial voltage Vi at the start of charging. The total voltage Vₜₒₜ may additionally include a compensation voltage V_{com} to account for a voltage drop that may occur due to the connection module 700. Therefore, the total voltage Vₜₒₜ may be greater than a cutoff voltage V_{cut-off} determined by the first resistance of the battery 100. In this case, the charging duration of the CC mode from a time point t₁ to a time point t₂ is confirmed to be 354 seconds, which is substantially the same as that in Comparative Example 3.

However, when no compensation voltage V_{com} is additionally applied in the CV mode, the terminal voltage of the battery 100 is maintained at a constant voltage V₂ less than the cutoff voltage V_{cut-off}, and the charging current of the battery 100 may decrease with time. When considering the point at which the SOC of the battery 100 rises to 80%, the duration of the CV mode from a time point t₂ to a time point t₃ is confirmed to be 818 seconds, which is greater than that in Comparative Example 3.

Therefore, in Embodiment 5, the total charging duration of the battery 100 from a time point t₁ to a time point t₃ is confirmed to be 1172 seconds, which is greater than 792 seconds in Comparative Example 3 but less than 1225 seconds in Comparative Example 4. In other words, it may be confirmed that due to the application of the compensation voltage V_{com} in the CC mode, the total charging duration decreases to be similar to that in Comparative Example 3.

Referring to FIG. 15, in Embodiment 6, a charging current I_{cv} in the CV mode may sequentially decrease from a constant current I_{cc}. The current measuring unit 500 may measure the charging current I_{cv} that sequentially decreases, and the processor 200 may adjust a charging voltage in real-time by reflecting the measured charging current lev. In this case, the charging voltage may be determined as a total voltage Vₜₒₜ that considers a compensation voltage V_{com}.

In Embodiment 6, the CV mode may proceed until the SOC of the battery 100 reaches a specified value, e.g., an SOC of 80%. In Embodiment 6, the CC mode lasts for 358 seconds, and the CV mode lasts for 457 seconds, confirming a total charging duration of 815 seconds.

Therefore, the total charging duration of the battery 100 in Embodiment 6 is confirmed to be less than 1225 seconds in Comparative Example 4. Additionally, the total charging duration of the battery 100 in Embodiment 6 is confirmed to be less than 1172 seconds in Embodiment 5. In other words, it may be confirmed that owing to the application of the compensation voltage V_{com} in both the CC mode and the CV mode, the total charging duration decreases to be similar to the total charging during in Comparative Example 3.

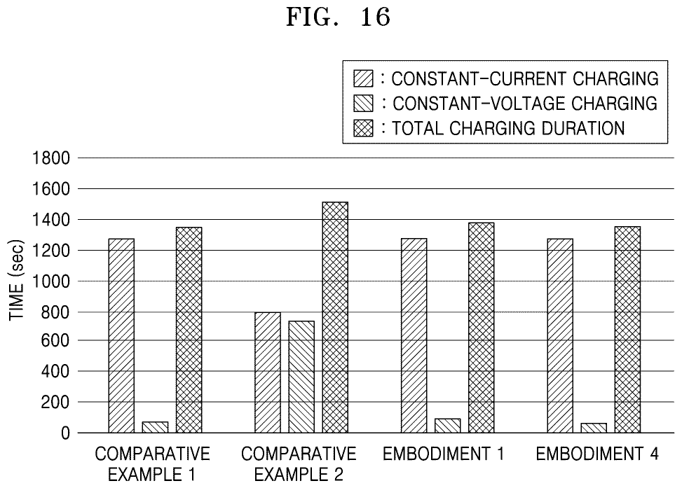

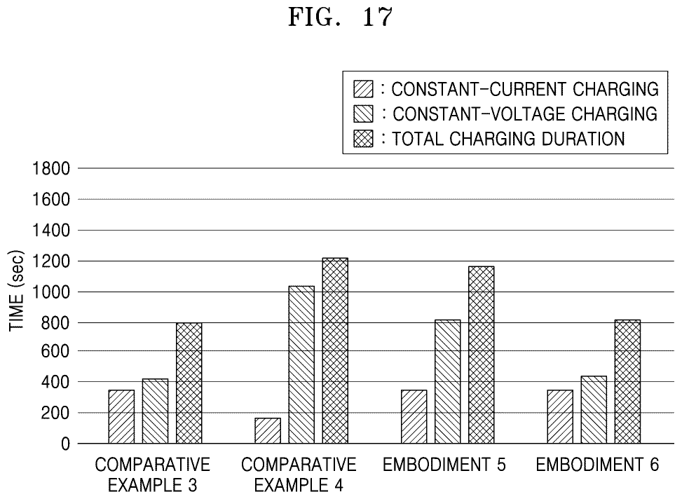

FIG. 16 is a graph comparing battery charging durations at a first C-rate. FIG. 17 is a graph comparing battery charging durations at a second C-rate.

The term “C-rate” refers to the rate at which a battery is charged or discharged relative to the maximum capacity of the battery and also refers to the current density at the rate. In an embodiment, 1C-rate or 1C refers to a rate at which a battery is fully charged or discharged in one hour relative to the maximum capacity of the battery, for example. A C-rate greater than 1C s desirable for relatively fast charging. However, when a battery is continuously charged with a relatively high current, a relatively large amount of heat may be generated in the battery, and each electrode of the battery may experience an overvoltage state due to the internal resistance of the battery. Therefore, the C-rate of a battery may be determined considering the type and characteristics of the battery.

FIGS. 16 and 17 show charging durations of the battery 100 at different C-rates. In an embodiment, a first C-rate may be less than a second C-rate. In an embodiment, the first C-rate may be 2C, and the second C-rate may be 4C, for example. In this case, charging durations of the battery 100 in Comparative Examples and Embodiments are shown in Table 1 below.

TABLE 1

| | | CC | CV | Total |
|---|---|---|---|---|
| | | charging | charging | charging |
| | C-rate | duration | duration | duration |
| | (C) | (sec) | (sec) | (sec) |
| Comparative Example 1 | 2 | 1272 | 67 | 1339 |
| Comparative Example 2 | 2 | 788 | 728 | 1516 |
| Comparative Example 3 | 4 | 356 | 436 | 792 |
| Comparative Example 4 | 4 | 182 | 1043 | 1225 |
| Embodiment 1 | 2 | 1268 | 102 | 1370 |
| Embodiment 4 | 2 | 1272 | 75 | 1347 |
| Embodiment 5 | 4 | 345 | 818 | 1172 |
| Embodiment 6 | 4 | 358 | 457 | 815 |

FIG. 16 shows that the charging duration in Embodiment 4 in which a compensation voltage V_{com} is applied in both the CC mode and the CV mode is substantially similar to the charging duration in Comparative Example 1 in which a second resistance is not generated by the connection module 700.

In addition, FIG. 17 shows that the charging duration in Embodiment 6 in which a compensation voltage V_{com} is applied in both the CC mode and the CV mode is substantially similar to the charging duration in Comparative Example 3 in which a second resistance is not generated by the connection module 700.

Furthermore, referring to FIGS. 16 and 17, it may be confirmed that, in Embodiments 1 and 4 in which charging is performed at the relatively low first C-rate, charging may be substantially completed in the CC mode. Thus, there is no significant difference between the total charging duration of Embodiment 1 in which a compensation voltage V_{com} is applied in the CV mode and the total charging duration of Embodiment 4 in which no compensation voltage V_{com} is applied in the CV mode.

In addition, when comparing Embodiments 5 and 6 in which charging is performed at the second C-rate greater than the first C-rate, significant charging may proceed in the CV mode. Thus, a longer total charging duration may be desired in Embodiment 5 in which no compensation voltage V_{com} is applied in the CV mode, compared to Embodiment 6 in which a compensation voltage V_{com} is applied in the CV mode.

Therefore, in an embodiment, the charging method of the battery 100 may be determined differently based on the C-rate of the battery 100. In an embodiment, when the battery 100 is charged at the relatively low first C-rate, the battery 100 may be charged in the CC mode based on a total voltage Vₜₒₜ to which a compensation voltage V_{com} added. Then, the battery 100 may be charged in the CV mode based on a cutoff voltage V_{cut-off} without adding a compensation voltage V_{com}, for example. However, when the battery 100 is charged at the relatively high second C-rate, the battery 100 may be charged based on a total voltage Vₜₒₜ to which a compensation voltage V_{com} is added in both the CC mode and the CV mode.

As described above, the charging method of the battery 100 may be differently determined based on the C-rate of the battery 100 to improve charging efficiency. However, the disclosure is not limited thereto. In an embodiment, the battery 100 may be charged based on a total voltage Vₜₒₜ to which a compensation voltage V_{com} is added in both the CC mode and the CV mode regardless of the C-rate of the battery 100 to reduce the charging duration of the battery 100, for example.

The battery charging state determination apparatus 20 may be disposed (e.g., mounted) on various electronic devices (such as walking aids, vehicles, or terminals) that include the battery 100.

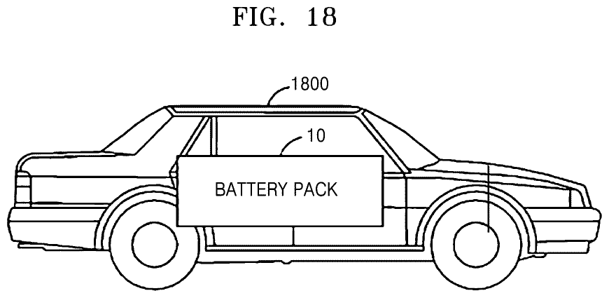

FIG. 18 is a diagram illustrating an embodiment of a vehicle 1800.

Referring to FIG. 18, the vehicle 1800 includes a battery pack 10. The vehicle 1800 may use the battery pack 10 as a power source. The vehicle 1800 may be an electric vehicle or a hybrid vehicle, for example.

The battery pack 10 includes a battery charging state determination apparatus 20 (refer to FIG. 1) and a battery 100 (refer to FIG. 1) (or battery modules). The battery charging state determination apparatus 20 may monitor whether an abnormality has occurred in the battery pack 10 and may prevent the battery pack 10 from being overcharged or over-discharged. Additionally, the battery charging state determination apparatus 20 may perform thermal control on the battery pack 10 when the temperature of the battery pack 10 exceeds a first temperature (e.g., 40 degrees Celsius (° C.)) or falls below a second temperature (e.g., −10° C.). Additionally, a battery management system (“BMS”) may perform cell balancing to equalize the SOCs of battery cells included in the battery pack 10.

In an embodiment, the battery charging state determination apparatus 20 charges the battery 100 (or battery modules) according to a charging profile. The battery charging state determination apparatus 20 may determine a charging profile for the battery 100 (or battery modules) or charging profiles respectively for the battery cells included in the battery 100.

The description provided above with reference to FIGS. 1 to 17 is also applicable to the example shown in FIG. 18 and is thus not repeated here.

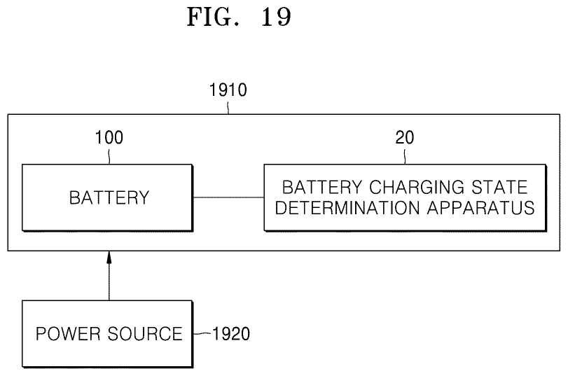

FIG. 19 is a diagram illustrating an embodiment of a terminal 1910.

Referring to FIG. 19, the terminal 1910 includes a battery charging state determination apparatus 20 and a battery 100 (or battery modules). The terminal 1910 may be a mobile terminal such as a smartphone, a laptop, a tablet PC, or a wearable device, but is not limited thereto.

The battery charging state determination apparatus 20 may be provided in the form of an integrated circuit (“IC”), but is not limited thereto.

The battery charging state determination apparatus 20 may receive power from a power source 1920 via a wired or wireless connection and may charge the battery 100 with the power based on a charging profile. In an embodiment, the battery charging state determination apparatus 20 may determine a charging profile for the battery 100.

The description provided above with reference to FIGS. 1 to 8 is also applicable to the embodiment shown in FIG. 19 and is thus not repeated here.

The embodiments described herein may be implemented using hardware, software and/or any combinations thereof. In an embodiment, devices, methods, and components described in the embodiments may be implemented using one or more general-purpose or special-purpose computers such as a processor, a controller, an arithmetic logic unit (“ALU”), a digital signal processor, a microcomputer, a field-programmable gate array (“FPGA”), a programmable logic unit (“PLU”), a microprocessor, or any other device capable of executing and responding to instructions, for example. Such a processing device may run an OS and one or more software applications that run on the OS, for example. In addition, the processing device may also access, store, manipulate, process, and create data in response to execution of software. Although one processing device is described for purpose of simplicity, those skilled in the art will appreciate that the processing device may include multiple processing elements and/or multiple types of processing elements. In an embodiment, the processing device may include a plurality of processors, or a single processor and a single controller, for example. In addition, different processing configurations are possible, such as parallel processors.

The software may include a computer program, a piece of code, an instruction, or any combinations thereof, and may independently or collectively instruct or configure the processing device to operate as desired. The software and/or data may be embodied permanently or temporarily in any type of machine, component, physical device, virtual equipment, computer storage medium, or device, or in propagated signal waves to provide instructions or data to the processing device or be interpreted by the processing device. The software may also be distributed over network-coupled computer systems so that the software may be stored and executed in a distributed fashion. The software and data may be stored in one or more non-transitory computer-readable recording media.

The methods of the embodiments may be implemented in the form of program instructions executable by various computing devices and may be recorded in non-transitory computer-readable recording media. The non-transitory computer-readable recording media may store, individually or in combination, program instructions, data files, data structures, or the like. The program instructions recorded on the media may be specially designed and constructed for the embodiments or may be of the kind well-known and available to those skilled in the field of computer software. In embodiments, the non-transitory computer-readable recording media may include: magnetic media such as hard disks, floppy disks, and magnetic tapes; optical recording media such as CD-ROMs and DVDs; magneto-optical media such as floptical disks; and hardware such as ROMs, RAMs, and flash memories specifically configured to store program instructions and execute the program instructions. In embodiments, the program instructions include not only machine language code such as that generated by a compiler but also high-level language code executable by a computer using an interpreter or the like.

The above-mentioned hardware devices may operate via one or more software modules to perform operations in the embodiments, and vice versa.

As described above, according to one or more of the embodiments described above, the method, computer program, and apparatus for determining the charging state of a battery may optimize the charging duration of the battery.

According to one or more of the embodiments described above, the method, computer program, and apparatus for determining the charging state of a battery may monitor the state of the battery during charging.

According to one or more of the embodiments described above, the method, computer program, and apparatus for determining the charging state of a battery may protect a battery system from risk situations in which overvoltage is applied to the battery during charging.

Although embodiments have been described with reference to the limited drawings, those skilled in the art may make various technical modifications and variations based thereon. For example, intended results may be achieved even when the techniques described above are performed in a different order, and/or components in a described system, architecture, device, or circuit are combined in a different manner and/or replaced or supplemented by other components or their equivalents.

Therefore, other implementations, other embodiments, and equivalents to the claims are also within the scope of the following claims.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A method of determining a battery charging state, the method comprising:
measuring a voltage of a battery by a voltage measuring unit;
calculating a compensation voltage for compensating for a voltage drop caused by a second resistance of a connection module disposed between the battery and the voltage measuring unit; and
charging the battery, based on a total voltage defined as a sum of the compensation voltage and a cut-off voltage which is determined by a first resistance of the battery.

2. The method of claim 1, wherein the battery comprises a plurality of battery cells, and
the connection module comprises:
a collector module electrically connecting electrodes of the plurality of battery cells to each other; and
a connection member disposed between the battery and the voltage measuring unit to electrically connect the battery and the voltage measuring unit to each other.

3. The method of claim 2, wherein the second resistance of the connection module is determined by adding up resistances generated by the collector module and the connection member.

4. The method of claim 1, wherein the charging the battery sequentially comprises:
charging the battery in a constant-current charging mode; and
charging the battery in a constant-voltage charging mode.

5. The method of claim 4, wherein, in the constant-current charging mode, a charging voltage increases to the total voltage.

6. The method of claim 5, wherein, in the constant-current charging mode, the compensation voltage is determined by a product of the second resistance and a current applied in the constant-current charging mode.

7. The method of claim 4, further comprising measuring a charging current of the battery by a current measuring unit,
wherein, in the constant-voltage charging mode, the charging the battery is performed in multiple steps by sequentially reducing a charging voltage.

8. The method of claim 7, wherein, in each of the multiple steps, the compensation voltage is determined by a product of the charging current and the second resistance.

9. The method of claim 8, wherein, in a first step of the multiple steps, constant-voltage charging the battery is performed with a first total voltage determined by a sum of the cut-off voltage and a compensation voltage which is determined by a product of the second resistance and a first charging current preset to be less than the charging current in the constant-current charging mode, and
when the charging current of the battery measured by the current measuring unit reduces to the first charging current, constant-voltage charging the battery is performed in a second step of the multiple steps with a second total voltage determined by a sum of the cut-off voltage and a compensation voltage which is determined by a product of the second resistance and a second charging current less than the first charging current.

10. The method of claim 4, further comprising measuring a current of the battery by a current measuring unit,
wherein, in the constant-voltage charging mode, the charging the battery is performed with a total voltage determined by a sum of the cut-off voltage and a compensation voltage which is determined by a product of the second resistance and the current of the battery measured in real time.

11. The method of claim 4, wherein the charging the battery is performed at a first C-rate,
wherein, in the constant-current charging mode, the charging the battery is performed based on the total voltage, and
in the constant-voltage charging mode, the charging the battery is performed based on the cut-off voltage.

12. The method of claim 4, wherein the charging the battery is performed at a second C-rate greater than a first C-rate,
wherein the charging the battery is performed based on the total voltage in the constant-current charging mode and the constant-voltage charging mode.

13. A non-transitory recording medium storing a computer executable program instructing a processor to execute a method comprising:
measuring a voltage of a battery by a voltage measuring unit;
calculating a compensation voltage for compensating for a voltage drop caused by a second resistance of a connection module disposed between the battery and the voltage measuring unit; and
charging the battery, based on a total voltage defined as a sum of the compensation voltage and a cut-off voltage which is determined by a first resistance of the battery.

14. An apparatus for determining a battery charging state of a battery and being connected to the battery by a connection module, the apparatus comprising:
a voltage measuring unit configured to measure a voltage of the battery;
a memory which stores a second resistance generated by the connection module disposed between the battery and the voltage measuring unit; and
a processor configured to calculate a compensation voltage which compensates for a voltage drop caused by the second resistance of the connection module and, based on a total voltage defined as a sum of the compensation voltage and a cut-off voltage which is determined by a first resistance of the battery, determine a charging state of the battery.

15. The apparatus of claim 14, wherein the battery comprises a plurality of battery cells, and
the connection module comprises:
a collector module which electrically connects the plurality of battery cells to each other; and
a connection member disposed between the battery and the voltage measuring unit which electrically connects the battery and the voltage measuring unit to each other,
wherein the processor is further configured to determine the second resistance of the connection module by adding up resistances of the collector module and the connection member.

16. The apparatus of claim 14, wherein the processor is further configured to control the battery to be charged in a constant-current charging mode, and when a set condition is satisfied, control the battery to be charged in a constant-voltage charging mode.

17. The apparatus of claim 16, wherein the processor is further configured to increase a charging voltage to the total voltage in the constant-current charging mode.

18. The apparatus of claim 17, wherein the processor is further configured to determine the compensation voltage as a product of the second resistance and a constant current of the battery in the constant-current charging mode.

19. The apparatus of claim 16, further comprising a current measuring unit configured to measure a current of the battery,
wherein the processor is further configured to determine the compensation voltage as a product of the second resistance and the current of the battery measured in the constant-voltage charging mode.

20. The apparatus of claim 16, further comprising a current measuring unit configured to measure a current of the battery,
wherein the processor is further configured to control the battery to be charged in multiple steps in the constant-voltage charging mode by sequentially reducing a charging voltage.
